(19) United States
(12) Patent Application Publication
(10) Pub. No.: US 2018/0090415 A1
(43) Pub. Date: Mar. 29, 2018

(54) HEAT DISSIPATING APPARATUSES WITH PHASE CHANGE MATERIALS

(71) Applicant: Hewlett Packard Enterprise Development LP, Houston, TX (US)

(72) Inventors: Sergio Escobar-Vargas, Santa Clara, CA (US); Cullen E. Bash, Los Gatos, CA (US); Niru Kumari, Palo Alto, CA (US)

(21) Appl. No.: 15/277,185

(22) Filed: Sep. 27, 2016

(51) Int. Cl. H01L 23/427; H01L 25/065

(52) U.S. Cl. CPC H01L 23/427; H01L 25/0657; H01L 2225/06582; H01L 2225/06562; H01L 2225/06589

(57) ABSTRACT

Examples described herein include heat dissipating apparatuses with phase change material. In some examples, a heat dissipating apparatus comprises a wick structure to carry a cooling fluid to cool an electronic heat source, a vapor region to carry heated cooling fluid away from the wick structure, and a compartmentalized space separate from the vapor region comprising a phase change material to absorb energy from the heated cooling fluid.

### BACKGROUND

During operation, electrical components of an electronic device may produce heat. The heat generated by these electrical components may be removed via thermally connected heat dissipating apparatuses and cooling devices.

### BRIEF DESCRIPTION OF THE DRAWINGS

The following detailed description references the drawings, wherein:

FIG. 1 illustrates a heat dissipating apparatus with phase change material, according to some examples.

FIG. 2 illustrates a heat dissipating apparatus with a first section, a second section, and a third section with phase change material, according to some examples.

FIG. 3 illustrates a heat dissipating apparatus with phase change material integrated into a package, according to some examples.

FIG. 4A illustrates a heat dissipating apparatus with a first phase change material and a second phase change material, according to some examples.

FIG. 4B illustrates a top view of a die of the heat dissipating apparatus of FIG. 4A, according to some examples.

FIG. 5 illustrates a heat dissipating apparatus with a heat sink, according to some examples.

FIG. 6 illustrates a heat dissipating apparatus with a fin structure, according to some examples.

FIG. 7 illustrates a heat dissipating apparatus with multiple segments in a phase change material, according to some examples.

FIG. 8 illustrates a top perspective view of a plate of a heat dissipating apparatus, according to some examples.

### DETAILED DESCRIPTION

In some examples, electrical components of an electrical device (e.g., computers, smartphones, personal digital assistants, game appliances, wearable devices, etc.) may include an integrated circuit (IC). During operation, an (IC) may quickly change from a state of low power consumption to a state of high power consumption. The IC may operate in a high power mode for a long period or it may operate in a continuous series of high power bursts. Both of these high power modes result in a temperature increase of the IC.

In some examples, the IC may be thermally connected to a cooling device (e.g., a fan, a pump, etc.). However, the thermally connected cooling device may react slowly to the quick temperature changes of the IC, requiring the IC to be throttled to prevent overheating and damage. Although throttling may allow the connecting cooling device time to remove heat from the IC and bring down temperature, throttling affects the IC operation and may limit the IC's performance.

Additionally, the bursts of power used by the IC may cause the connected cooling device to cycle depending on the temperature oscillations of the IC. For example, the amplitude of the IC temperature swings may mean that a connected cooling fan increases its flow delivery for a short period. This cycling may shorten the lifetime of the connected cooling device and decrease the reliability of the cooling device.

Examples disclosed herein address these challenges by providing a heat dissipating apparatus that absorbs heat generated from quick bursts of power used by an electronic heat source and presents a steady thermal state. The heat dissipating apparatus comprises a wick structure that carries a cooling fluid. The cooling fluid absorbs energy from the electronic heat source, thus turning into vapor. The vapor rises in a vapor region of the heat dissipating apparatus. The heat dissipating apparatus comprises a phase change material (PCM) in a compartment separate from the vapor region and the wick structure. Energy in the vapor is transferred to the PCM. The PCM has a high latent heat and maintains a constant temperature while absorbing the energy from the vapor. This dampens the temperature peaks produced by the electronic heat source. Thus, examples disclosed herein allow for quick heat removal from the electronic heat source. Additionally, because the temperature of the PCM remains constant while it absorbs energy, examples disclosed herein may present a steady thermal state to any connected cooling device such that the connected cooling device is not affected by the power bursts used by the electronic heat source.

In some examples, a heat dissipating apparatus comprises a wick structure, a vapor region, and a compartmentalized space separate from the vapor region. The wick structure is to carry a cooling fluid to cool an electronic heat source. The vapor region is to carry heated cooling fluid away from the wick structure. The compartmentalized space comprises a phase change material to absorb energy from the heated cooling fluid.

In some examples, a heat dissipating apparatus comprises a first compartment and a second compartment. The first compartment houses a plurality of conduits and a vapor region. The plurality of conduits is to carry a liquid form of a fluid to an interface area heated by an electronic heat source. The vapor region is to transport a vapor form of the fluid from the interface area. The second compartment houses a first phase change material to absorb energy from the vapor form of the fluid.

In some examples, a heat dissipating apparatus comprises a first section, a second section, a third section, and a barrier to separate the third section from the first section and the second section. The first section comprises a first wick structure to carry a liquid form of a first fluid and a first vapor region to transport a vapor form of the first fluid from the first wick structure. The second section comprises a second wick structure to carry a liquid form of a second fluid and a second vapor region to transport a vapor form of the second fluid from the second wick structure. The third section comprises a phase change material to absorb energy from the vapor from of the first fluid and to absorb energy from the vapor form of the second fluid.

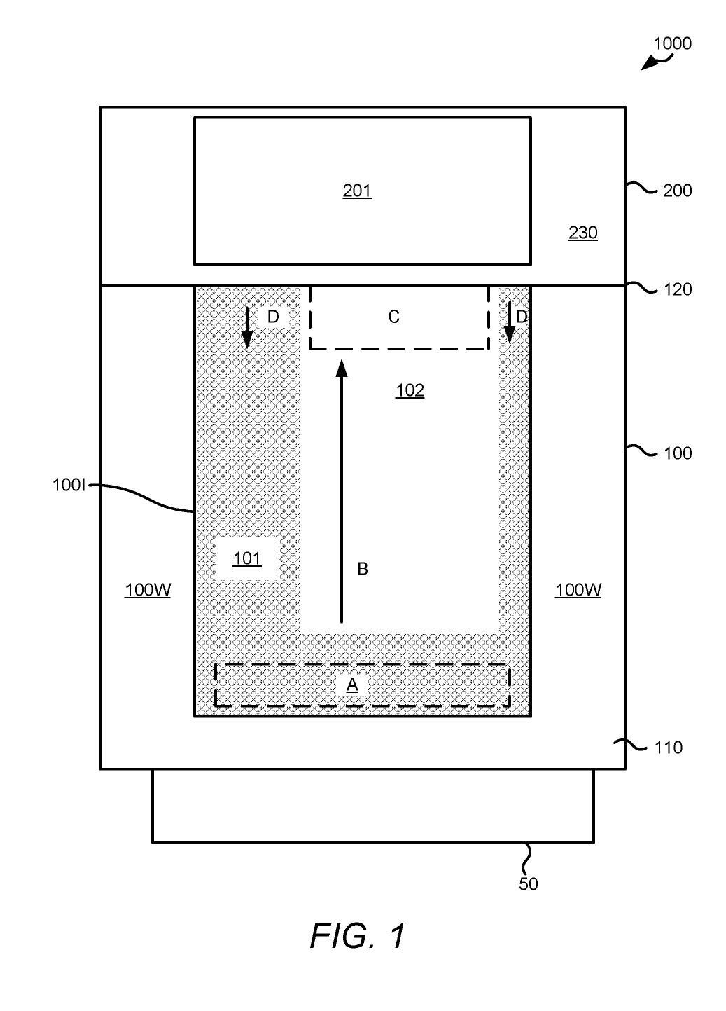

Referring now to the figures, FIG. 1 illustrates a heat dissipating apparatus 1000. Heat dissipating apparatus 1000 comprises a wick structure 101, a vapor region 102, and a compartmentalized space 200 separate from the vapor region 102 comprising a phase change material 201. In some examples, and as shown in FIG. 1, wick structure 101 and vapor region 102 are housed in a first compartment 100. In those examples, compartmentalized space 200 may also be characterized as a second compartment relative to the first compartment 100. Heat dissipating apparatus 1000 may interface with an electronic heat source 50 to remove heat generated by the electronic heat source 50.

In some examples, and as shown in FIG. 1, electronic heat source 50 may be an integrated circuit (IC) package. An IC package may include a substrate on which functional elements are formed. These substrates with the formed functional elements may be characterized as a die. In some examples, the functional elements formed on the substrate of a die may include circuitry (including, as examples, any or some combination of transistors, diodes, capacitors, resistors, optical elements, electrically conductive traces). For example, the circuitry of a die may form a microprocessor, a core of a microprocessor, a programmable gate array, an application-specific integrated circuit (ASIC) component, a memory, an input/output (I/O) component, etc., or any combination thereof. IC package may include a stack of dies on a substrate, in which one die is provided over (stacked) another die to form a three-dimensional (3D) configuration. A housing may connect to the substrate to cover the stack of dies to provide a barrier of the dies from an outside environment. The operation of the circuitry on the dies may cause the IC package to generate heat, which is removed by heat dissipating apparatus 1000. In other examples, electronic heat source 50 may be the die itself, rather than the entire IC package. In these examples, and as shown in FIG. 3, for example, heat dissipating apparatus may be integrated inside the IC package instead of being located outside the IC package.

Referring back to FIG. 1, first compartment 100 may comprise a first plate 110, a wall 100W, and a second plate 120. The wall 100W may have an internal surface 1001 that forms an internal chamber with first plate 110 and second plate 120. First plate 110, wall 100W, and second plate 120 may be comprised of a metallic material that may have high heat conductivity. First plate 110 may directly touch electronic heat source (e.g., IC package). Second plate 120 may touch second compartment 200.

The internal chamber of first compartment 100 may include a cooling fluid that is kept in wick structure 101. In some examples, cooling fluid may be in liquid form. Non-limiting examples of a cooling fluid may be water, a dielectric fluid, etc. Wick structure 101 may be comprised of a layer of material that is formed to allow the cooling fluid to move through wick structure 101. In other words, wick structure 101 may include an arrangement of elements that define pathways to allow for movement of the cooling fluid by capillary effect. In some examples, the wick structure 101 may include a plurality of conduits throughout the wick structure. The plurality of conduits allow for a high surface area and increases the cooling fluid movement through the wick structure via capillary action. In some examples, wick structure 101 may be comprised of a metallic sintered powder coating (e.g., copper, etc.) that is deposited on the internal surface 1001 of first compartment 100. In other examples, wick structure 101 may be a porous tube-like structure that is attached to the internal surface 1001. In some examples, the wick structure 101 may include nanoparticles or a nanomesh. Nanoparticles may include elements of a material that have dimensions on a nanometer scale, e.g., less than 100 nanometers. A nanomesh may include a crossing arrangement of elements of a material, where the elements have dimensions on a nanometer scale. In examples where electronic heat source 50 is an integrated IC package (e.g., the heat dissipating apparatus it outside the IC package), wicking structure 101 may be comprised of a copper coating. In other examples where electronic heat source 50 is a die in an integrated IC package (e.g., the heat dissipating apparatus is inside the IC package), wicking structure may comprise silicon dioxide.

In some examples, wick structure 101 comprises an interface area A that interfaces with electronic heat source 50. At this interface area A, cooling fluid may absorb heat that is generated by electronic heat source 50 and transferred via conduction through first plate 110 of first compartment 100 to interface area A. In some examples, the amount of cooling fluid kept in wick structure 101 is such that there is a thin layer of fluid over interface area A. This is because a thin layer of fluid (relative to a thick layer of fluid) decreases the time it takes for the cooling fluid to be heated. This decreases the time it takes for energy to be absorbed from the electronic heat source 50.

After the cooling fluid is heated, the cooling fluid may turn from one state of matter to another state of matter. For example, the cooling fluid may be in liquid form. After being heated at interface area A, the cooling fluid may turn into its vapor form. Due to the pressure differences present in the first compartment 100, the heated cooling fluid (e.g., in its vapor form) may rise in vapor region 102 as indicated by arrow B. In some examples, vapor region 102 is an empty space that may hold the heated cooling fluid. The heated cooling fluid rises due to pressure differences until it reaches second plate 120 and dotted area C of first compartment. The energy held in the heated cooling fluid is transferred through second plate 120 via conduction to second compartment 200. Second compartment 200 may be comprised of a third plate 230. Third plate 230 like, first plate 110 and second plate 120, may be comprised of a metallic material that has a high heat conductivity. Third plate 230 may comprise a cavity to for a phase change material 201. The energy from the heated cooling fluid may be transferred via conduction through third plate 230 to the cavity that holds phase change material 201. Accordingly, the energy carried by the heated cooling fluid is absorbed by phase change material 201. The heated cooling fluid cools back to its unheated state (e.g. condenses back to its liquid form) and wick structure 101 may carry it down towards interface area A, as indicated by arrow D.

As used herein, a phase change material is a material that may absorb a high amount of thermal energy during the processing of melting from a solid to a liquid while remaining at a constant temperature. Accordingly, phase change material 201 is a material with a high latent heat (specifically, a high heat of fusion). The high latent heat of phase change material 201 allows the phase change material 201 to absorb a high amount of energy from the heated cooling fluid and maintain a steady temperature. In some examples, phase change material may be comprised of paraffin wax (e.g., C18). In some examples, phase change material 201 may have a latent heat of 206.5 kJ/kg. Accordingly, phase change material 201 may dampen the temperature peaks that are caused by the electronic heat source 50.

For example, phase change material 201 in second compartment may have a volume of 3×10⁻⁵ m³ with a latent heat of 206.kJ/kg. Electronic heat source 50 may be a 200 W heat source. In this example, phase change material 201 may take 26 seconds to change from a solid phase to a liquid phase. During the 26 seconds, phase change material's high latent heat (high heat of fusion) allows phase change material 201 to absorb energy in the form of latent heat while the temperature of phase change material 201 remains constant. Accordingly, any cooling device, such as a fan, that may be thermally connected to second compartment 200 may operate at steady state to extract energy from the phase change material during the 26 seconds.

In some examples, phase change material 201 is contained in its cavity and does not physically integrate with first compartment 100 (e,g,, phase change material 201 cannot melt to touch second plate 120 of first compartment 100 or cannot melt into vapor region 102). Accordingly, second plate 120 and a portion of third plate 230 may act as barriers to contain phase change material 201. Although heat dissipating apparatus 1000 is shown as interfacing with one electronic heat source 50, heat dissipating apparatus 1000 is not limited to interfacing with the number of electronic heat sources shown.

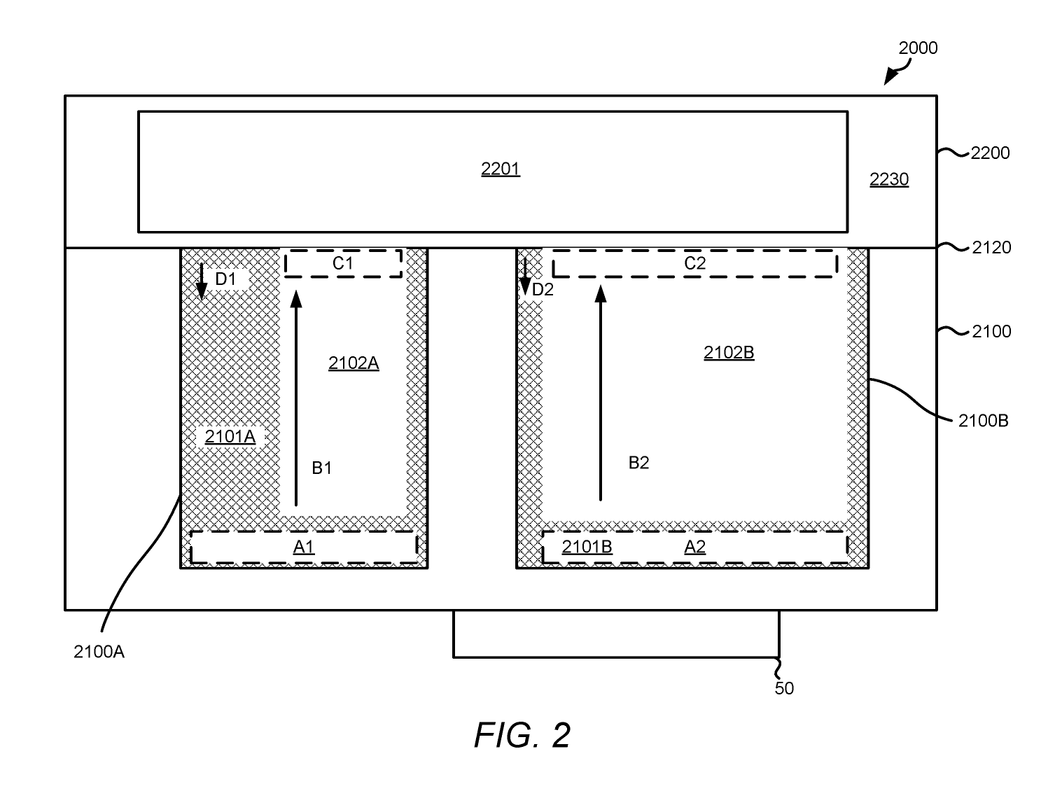

FIG. 2 illustrates a heat dissipating apparatus 2000. Heat dissipating apparatus 2000 is similar to heat dissipating apparatus 1000 except that heat dissipating apparatus 2000 has a first compartment 2100 that comprises a first section 2100A and a second section 2100B. First section 2100A has a first wick structure 2101A and a first vapor region 2102A. First section 2100A may also have its own interface area A1. First wick structure 2101A may carry a liquid form of a first cooling fluid to interface area A1 that interfaces with electronic heat source 50. In some examples, and as discussed above in relation to wick structure 101, first wick structure 2101A may do this via capillary action. At interface area A1, the liquid form of the first cooling fluid may be heated, turning into a vapor form of the first cooling fluid. The first vapor region 2102A may transport the vapor form of the first cooling fluid from the wick structure 2101A up to region C1.

Second section 2100B may have a second wick structure 2101B and a second vapor region 2102B. Second section 2100B may also have its own interface area A2. Second wick structure 2102B may carry a liquid form of a second cooling fluid to interface area A2 via capillary action. At interface area A2, second cooling fluid may be heated, turning into a vapor form of the second cooling fluid. The second vapor region 2102B may transport the vapor form of the second cooling fluid from the second wick structure 2102B up to region C2.

Region C1 of first section 2100A and region C2 of second section 2100B may interface with second compartment 2200, which may also be characterized as a third section in relation to first section and second section. Second compartment 2200 may comprise a phase change material 2201. In some examples, second compartment 2200 may include a cavity that is filled with phase change material 2201. Phase change material 2201 may absorb energy from the vapor form of the first cooling fluid (at region C1) and the vapor form of the second cooling fluid (at region C2). Accordingly, first section 2100A and second section 2100B may both transfer energy from electronic heat source 50 up to second compartment 2200 and phase change material 2201. Phase change material 2201 is similar to phase change material 201. Accordingly, phase change material 2201 dampens the temperature peaks that would be caused by electronic heat source 50 by absorbing energy and maintaining a steady temperature.

When energy from the vapor form of the first cooling fluid is absorbed by phase change material 2201, the vapor form of the first cooling fluid may condense back to its liquid form. First wick structure 2101A may carry the liquid form of the first cooling fluid back to the interface area A1. This is represented by arrow D1. Similarly, when energy from the vapor form of the second cooling fluid is absorbed by phase change material 2201, the vapor form of the second cooling fluid may condense back to its liquid form. Second wick structure 2101B may carry the liquid form of the second cooling fluid back to the interface area A2. This is represented by arrow D2.

In some examples, and as discussed above in relation to first compartment 100 and second compartment 200, there is a barrier between first section 2100A, second section 2100B;, and third section 2200 (i.e., second compartment). The barrier may contain the phase change material in the third section 2200 such that it cannot physically integrate with first section 2100A, and second section 2100B. Thus, in some examples, second plate 2120 and a portion of third plate 2230 may act as a barrier.

FIG. 3 illustrates a heat dissipating apparatus 3000. Unlike heat dissipating apparatus 1000 and heat dissipating apparatus 2000, which is described as being outside of an IC package, heat dissipating apparatus 3000 is integrated inside an IC package. Accordingly, an electronic heat source 50 for heat dissipating apparatus 3000 may be a die inside the IC package.

Heat dissipating apparatus 3000 may include a first compartment 3100 and a second compartment 3200. First compartment 3100 may be an internal chamber 3055 of an IC package. Second compartment 3200 may be a housing that 3056 that covers the internal chamber 3055. Housing may be comprised of a metallic material (e.g., copper, aluminum, etc.) or a metallic alloy. The internal chamber 3055 of the IC package may include a stack of dies including first die 3052A, second die 3052B, etc. that is mounted on an upper surface of a substrate 3051. Electrical communication between the stack of dies and electrically conductive traces and other conductive elements of substrate may be provided through solder bumps 3052 between the bottom side of the stack of dies and the substrate 3051. In some examples, the solder bumps 3052 may be formed of an electrically conductive material, such as copper, another type of metal, or any other type of electrically conductive material.

First compartment 3100 (internal chamber 3055) may have wick structure 3101A that is formed on the internal surface of internal chamber 3055. Wick structure 3101A may be similar to wick structure 101, and wick structure 2101A. The wick structure 3101A extends along the internal surface of internal chamber 3055 and also extends at least partially along the upper surface of substrate 3051. Wick structure 3101A may carry a cooling fluid. Cooling fluid may be comprised of a dielectric fluid so as to safely interact with electronic circuitry of the dies.

First compartment 3100 (internal chamber 3055) may also comprise a vapor region 3102A. Vapor region 3102A may be comprised of a conduit that intersects first die 3052A, extending at least partially through first die 3052A. Vapor region 3102A may also extend through second die 3052B and subsequent other dies that are present in the stack in internal chamber 3055. Accordingly, vapor region 3102A may be characterized as a conduit that extends vertically through multiple dies, or an “inter-die” conduit. Thus, in a stack of dies that are arranged one over another, vapor region 3102A may extend along the vertical axis of the stack of dies. Vapor region 3102A may be comprised of an empty space that may hold or transfer heated cooling fluid. The empty space may also be surrounded a wick structure (as indicated by the patterned regions in 3102A). The wick structure that is present in vapor region 3102A may be similar to wick structure 3101A. In some examples, and as shown in FIG. 3, vapor region 3102A is comprised of two separate conduits, running parallel to each other.

In some examples, first die 3052A may comprise through-die conduits 3107 that extend in first die 3052A but does not extend to the other dies in the stack. In some examples, through-die conduits 3107 may be characterized as “microchannels.” As used herein, a “microchannel” may refer to a conduit that has a hydraulic diameter that is less than 1 millimeter. In some examples, and while not shown in FIG. 3, through-die conduits 3107 may include an empty space to carry heated cooling fluid (such as in vapor form) and a wick structure to carry cooling fluid (such as in liquid form). Wick structure in through-die conduits 3107 may be similar to wick structure 3102A.

In some examples, first die 3052A may also comprise connecting channels 3120A. Connecting channel 3120A may connect a vapor region 3102A to a through die conduits 3107. Connecting channel 3120 may carry a cooling fluid between the vapor region 3102A and the connected through-die conduit 317. Accordingly, in some examples, connecting channel 3120A may also include an empty space to hold a heated cooling fluid (e.g., in vapor form) and a wick structure to hold a cooling fluid (e.g., in liquid form).

Second compartment 3200 (housing 3056) of IC package may comprise a phase change material 3201 that is housed within the thickness of second compartment 3200. Phase change material 3201 may be similar to phase change material 201, and phase change material 2201 as described above. Housing 3056 may act as a barrier to contain phase change material within housing 3056. Accordingly, phase change material 3201 may not physically integrate with internal chamber 3055.

During operation of the integrated circuit and the stack of dies, wick structure 3101A carries a dielectric cooling fluid to the bottom of the stack of dies. From there, the wick structure in vapor region 3102A may carry, via capillary affect, the cooling fluid from the bottom to the first die 3052A, which may be an electronic heat source 50 due to its circuitry (not shown in FIG. 3). The cooling fluid may be dispersed throughout the surface area of the first die 3052A via connecting channels 3120A and through-die conduits 3107. The dispersed cooling fluid in the through-die conduits 3107 may be heated by the circuitry present in the die, thus turning the liquid form of the cooling fluid into its vapor form. The heated cooling fluid may then be carried away from the electronic heat source 50 via the through-die conduits 3107 and connecting channel 3052A into vapor region 3102A. The heated cooling fluid then reaches the area of the internal chamber 3055 that is outlined by dotted lines. In this area, the energy carried by the heated cooling fluid is transferred via conduction through the housing 3056 to phase change material 3201. The energy is absorbed by phase change material 3201. Accordingly, phase change material 3201 dampens the temperature spikes generated by the specific dies in the IC package. The cooled heated cooling fluid condenses and is carried by wick structure 3101A back down to the bottom of the die stack.

In some examples, internal chamber 3055 may have two sections, each section with its own wick structure, and vapor region. For example, and as shown in FIG. 3, internal chamber 3055 may have a second wick structure 3101B that carries a second cooling fluid. Second cooling fluid may be similar to the cooling fluid carried by wick structure 3101A. Additionally, internal chamber 3055 may have a second vapor region 3102B that also extends through multiple dies. In some examples, wick structure 3101A and vapor region 3102A may help to remove heat generated on one side of the die stack while wick structure 3101B and vapor region 3102B may help to remove heat generated on the other side of the die stack. In these examples, each die may have through-die conduits and connecting channels on both sides (for example, connecting channel 3120A for the left side of the die and connecting channel 3120B for the right side of the die.) Additionally, in these examples, second compartment 3200 and phase change material 3201 may be characterized as a third section that absorbs energy from both sides. In some examples, and as shown in FIG. 3, each die may have its own through-die conduit and connecting channel to connect the through die conduit to the vapor regions 3102A and/or 3102B. For example, second die 3052B may have its own through-die conduits and connecting channel that allows it to connect to vapor region 3102A.

FIG. 4A illustrates heat dissipating apparatus 4000. Heat dissipating apparatus 4000 is similar to heat dissipating apparatus 3000, except that heat dissipating apparatus 4000 may have extra phase change material in addition to phase change material 4201. For example, additional phase change material may be included in the internal chamber 4055 and integrated in the die.

In some examples, and as shown in FIG. 4A, first die 4052A may have channel 4103 that is filled with phase change material. First die 4052A may also have other channels, 4104, 4105, 4106 that are filled with phase change material. The phase change material in these channels may be the same material as phase change material 4201 or they may be comprised of different materials. In some examples, these channels may be comprised of silicon dioxide, which may form a barrier between the die and the phase change material such that the phase change material in these channels are contained within the channels (i.e., they cannot melt into the remainder of the die). These channels with the phase change material may help to further dampen the temperature changes generated by the circuitry of the dies. While FIG. 4A shows heat dissipating apparatus 4000 as having a number of channels comprising additional phase change material, heat dissipating apparatus 4000 is not limited to the number of additional channels with phase change material shown. Heat dissipating apparatus 4000 is also not limited to the configuration or placement of these additional channels. For example, each die in the stack may have additional channels with phase change material.

FIG. 4B shows a top view of first die 4052A of dissipating heat apparatus 4000. As can be seen in FIG. 4B, through-die conduits 4107 run parallel to the surface of first die 4052A while vapor regions 4102A and 4102B run perpendicular to the surface of first die 4052A. Circuitry 4060 is also visible in FIG. 48. Additional channels 4103, 4104, 4105, and 4106 are visible here because they have a width that is thicker than the corresponding connecting channels 4101A and 4101B. In other examples, additional channels 4103, 4104, 4105, and 4106 may be of similar width as connecting channels 4104A and 4104B and such would not be visible.

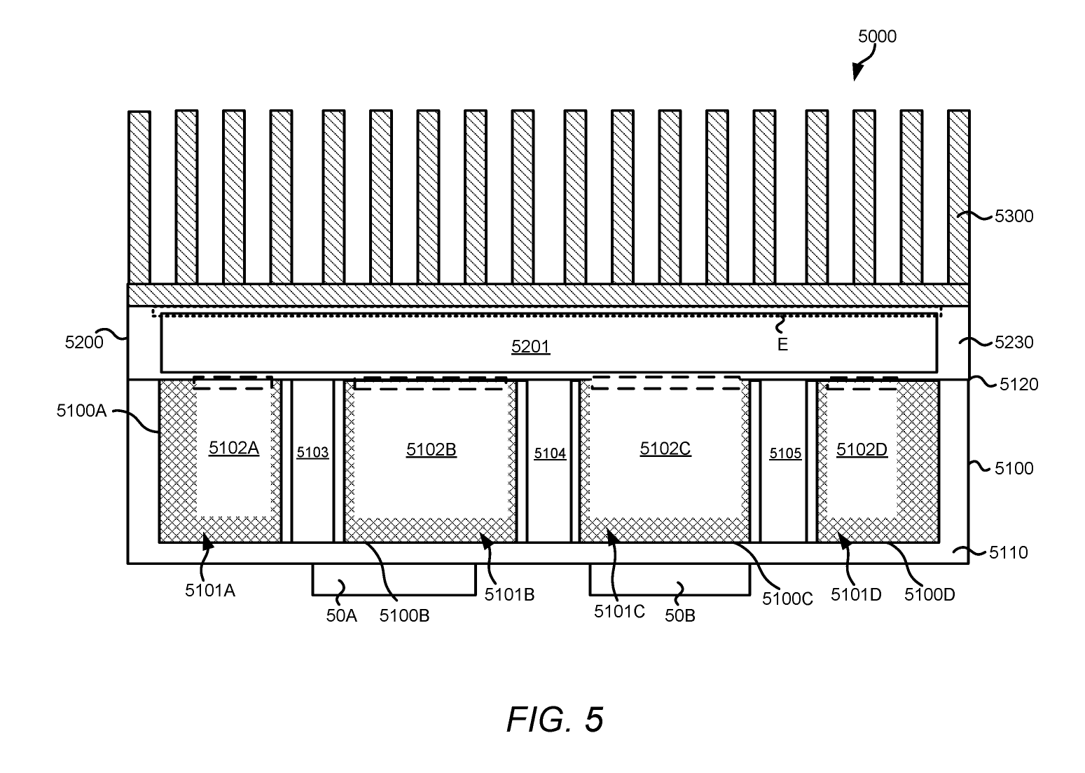

FIG. 5 illustrates heat dissipating apparatus 5000. Heat dissipating apparatus 5000 is similar to heat dissipating apparatus 2000, except that first compartment 5100 of heat dissipating apparatus 5000 comprises third section 5100C and fourth section 5100D in addition to first section 5100A and second section 5100B. Each section comprises its own wick structure (5101A, 5101B, 5101C, and 5101D) and its own vapor region (5102A, 5102B, 5102C, and 5102D). Additionally, heat dissipating apparatus 5000 also comprises additional phase change material that is housed in first compartment 5100 in addition to phase change material 5201 housed in second compartment 5200. For example, and as shown in FIG. 5, heat dissipating apparatus 5000 may comprise pillars between first section 5100A, second section 5100B, third section 5100C, and fourth section 5100D. These pillars may be filled with phase change material 5103, 5104, and 5105, respectively. Phase change materials 5103, 5104, and 5105 may be comprised of different or similar material to each other. Additionally, they may be comprised of different or similar material to phase change material 5201. In some examples, phase change material 5103, 5104, and 5105 are contained in their respective pillars and do not physically connect with phase change material 5201 or first section, second section, third section, and fourth section.

Because phase change material 5103, 5104, and 5105 may absorb energy from first, second, third, and fourth sections, these pillars filled with additional phase change material may help to further dampen the temperature peaks experienced by electronic heat sources 50A and 50B. Additionally, these pillars filled with additional phase change material may help to increase energy transfer to phase change material 5201 because energy from phase change material 5103, 5104, and 5105 may be transferred to phase change material 5201 via conduction through second plate 5120 and top plate 5230.

Heat dissipating apparatus 5000 additionally comprises a heat sink 5300. Accordingly, the energy absorbed by phase change material 5201 (e.g., from first section, second section, third section, fourth section, phase change material 5103-5105) may be removed from phase change material 5201 through heat sink 5300 in the F dotted region. In some examples, an airflow may be generated to carry heat away from heat sink 5300. Although not shown, in some examples, heat dissipating apparatus 5000 may also comprise a mechanical cooling device such as a fan to generate the airflow. The fan may operate in steady state until it senses a temperature change from phase change material 5201, which does not occur until phase change material changes from one form of matter to another form of matter (e.g., from a solid to a liquid). In other examples, instead of or in addition to heat sink 5300, other external cooling subsystems may be employed, such as a liquid cold plate, etc.

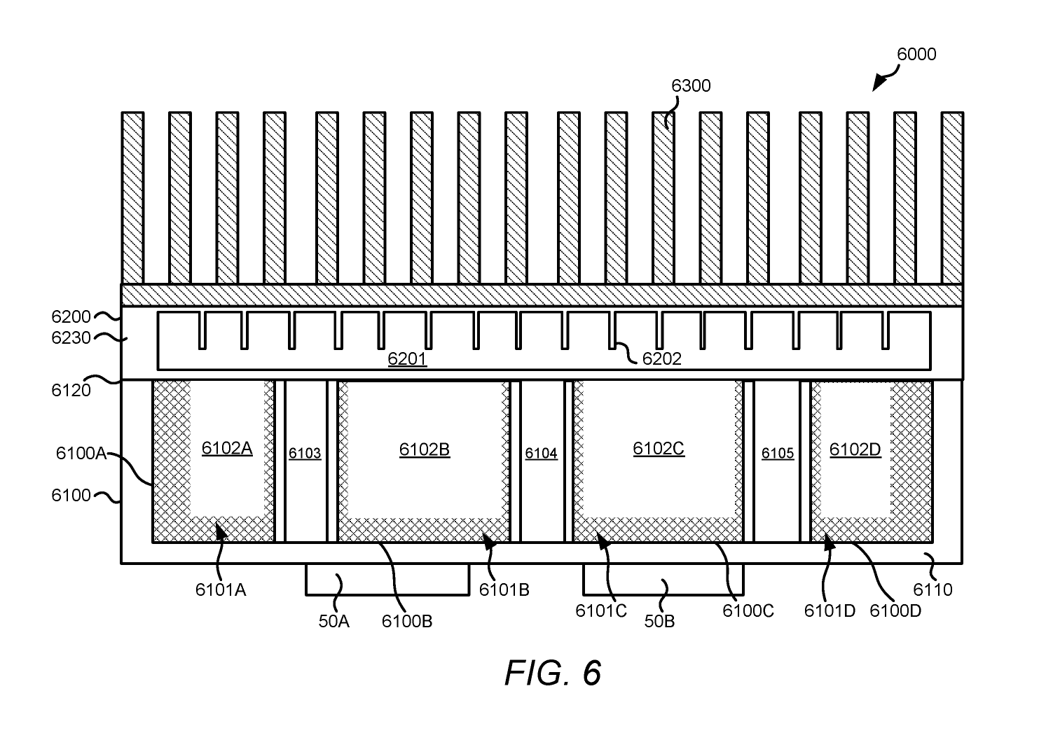

FIG. 6 illustrates a heat dissipating apparatus 6000. Heat dissipating apparatus 6000 is similar to heat dissipating apparatus 5000, except that the second compartment 6200 may comprise a fin structure 6202. Fin structure 6202 may protrude into phase change material 6201 to further facilitate the heat sink 6300's ability to remove energy away from phase change material 6201 by providing increased surface area. Fin structure 6202 may be comprised of a similar material as the material of third plate 6230. Accordingly, energy from phase change material 6201 may be transferred via conduction through the increased surface area provided by fin structure 6202.

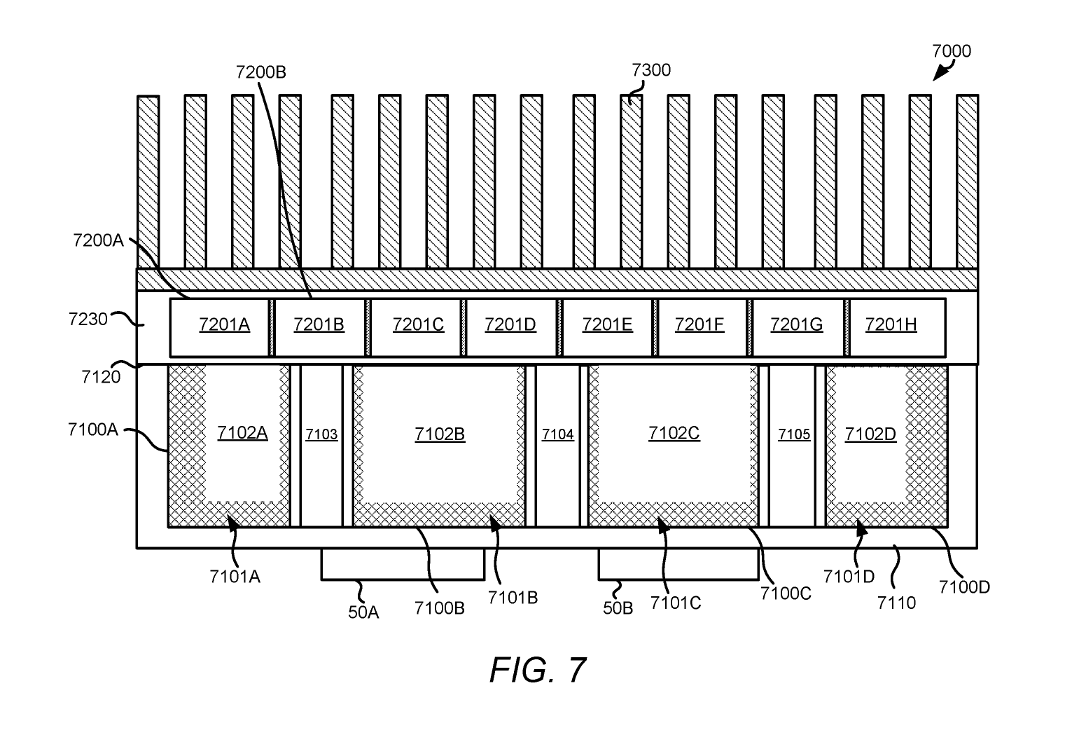

FIG. 7 illustrates a heat dissipating apparatus 7000. Heat dissipating apparatus 7000 is similar to heat dissipating apparatus 5000, except that second compartment 7200 may comprise a plurality of cavities, including a first cavity 7200A to hold phase change material 7201A, a second cavity 7200B to hold phase change material 7201B, etc. Accordingly, as compared to phase change material 5201 in heat dissipating apparatus 5000, the phase change material housed within second compartment 7230 is within separate cavities. These separate cavities allowed increased surface area for the phase change material to transfer energy to third plate 7230 and to heat sink 7300. Thus, these separate cavities may increase the transfer of energy between second compartment 7200 and heat sink 7300.

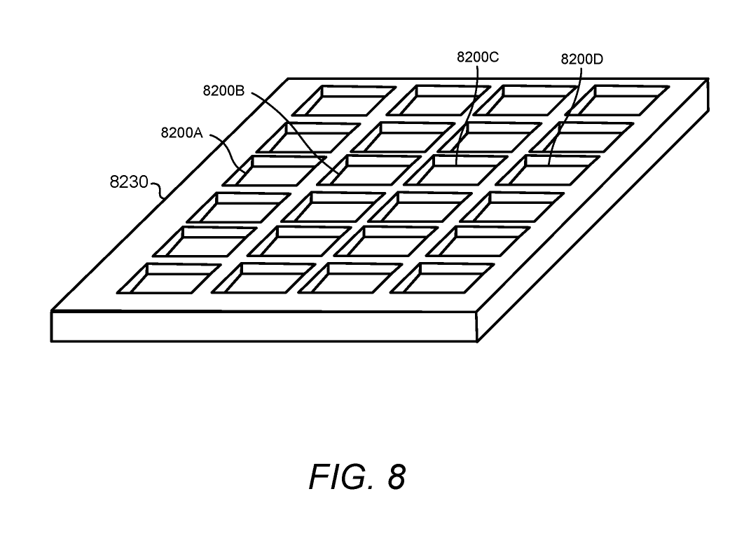

FIG. 8 illustrates a top perspective view of a third plate 8230 with multiple cavities 8200A, 8200B, 8200C, etc. In operation, these cavities may be filled with phase change material (not shown in FIG. 8.)

In the foregoing description, numerous details are set forth to provide an understanding of the subject disclosed herein. However, implementations may be practiced without some of these details. Other implementations may include modifications and variations from the details discussed above.

All of the features disclosed in this specification (including any accompanying claims, abstract and drawings), and/or all of the elements of any method or process so disclosed, may be combined in any combination, except combinations where at least some of such features and/or elements are mutually exclusive. For example, heat dissipating apparatus 3000 and heat sink apparatus 4000 may include a heat sink, as is described in relation to heat sink apparatus 5000

1. A heat dissipating apparatus comprising:
a first compartment having a first plate, a second plate, and walls separating the second plate from the first plate, a space between the first plate, the second plate, and the walls forming a vapor region in the first compartment, wherein the first plate is to be in direct thermal contact with an electronic heat source;
a wick structure provided in the vapor region to carry a cooling fluid to collect and direct heat from the electronic heat source, wherein the vapor region is to carry heated cooling fluid away from the wick structure; and
a second compartment in direct thermal contact with the second plate and positioned directly above the vapor region, the second compartment having a compartmentalized space that is separate from the vapor region and comprises a phase change material to absorb energy from the heated cooling fluid.

2. The heat dissipating apparatus of claim 1, comprising a heat sink that interfaces with the compartmentalized space to transfer energy from the phase change material.

3. The heat dissipating apparatus of claim 1, wherein the electronic heat source is a packaged integrated circuit assembly and is in direct thermal contact with the electronic heat source along the first plate.

4. The heat dissipating apparatus of claim 3, wherein the first compartment and the second compartment comprise a metal enclosure encompassing the wick structure, the vapor region, and the compartmentalized space, and wherein the first compartment has a common cross-sectional area as the second compartment.

5. The heat dissipating apparatus of claim 4, wherein the metal enclosure comprises a third plate that forms part of the compartmentalized space.

6. The heat dissipating apparatus of claim 1,
wherein the wick structure, the vapor region, and the compartmentalized space are within a packaged integrated circuit assembly; and
wherein the electronic heat source is a first die comprising a first circuitry.

7. The heat dissipating apparatus of claim 6, wherein the vapor region is a channel that runs through the first die.

8. The heat dissipating apparatus of claim 1, wherein the phase change material comprises paraffin wax.

9. The heat dissipating apparatus of claim 1, wherein the compartmentalized space comprises a first cavity and a second cavity.

10. A heat dissipating apparatus comprising:
a first compartment having a first plate, a second plate, and walls separating the second plate from the first plate, a space between the first plate, the second plate, and the walls forming a vapor region in the first compartment, wherein the first plate is to be in direct thermal contact with an electronic heat source, the first compartment housing a plurality of conduits to carry a liquid form of a fluid to an interface area heated by the electronic heat source, wherein the vapor region is to transport a vapor form of the fluid from the interface area; and
a second compartment in direct thermal contact with the second plate, the second compartment housing a first phase change material to absorb energy from the vapor form of the fluid in the vapor region, wherein the first compartment is positioned between the electronic heat source and the second compartment.

11. The heat dissipating apparatus of claim 10, wherein the first compartment occupies a same cross-sectional area as the second compartment.

12. The heat dissipating apparatus of claim 10, comprising a heat sink that interfaces with the second compartment to transfer energy from the phase change material.

13. The heat dissipating apparatus of claim 10, wherein the first compartment houses a second phase change material to absorb energy from the vapor form of the fluid.

14. The heat dissipating apparatus of claim 10,
wherein the electronic heat source is a packaged integrated circuit assembly; and
wherein the first compartment comprises a first plate touches the packaged integrated circuit assembly.

15. The heat dissipating apparatus of claim 14, wherein the first compartment comprises a second plate that touches the second compartment.

16. The heat dissipating apparatus of claim 11, wherein the first compartment is an internal cavity of a packaged integrated circuit assembly.

17. The heat dissipating apparatus of claim 16, wherein the second compartment is integrated inside a housing of the packaged integrated circuit assembly.

18. The heat dissipating apparatus of claim 16,
wherein the first compartment comprises a first die; and
wherein the vapor region extends through the first die.

19. A heat dissipating apparatus comprising:
a first section comprising a first wick structure to carry a liquid form of a first fluid, and a first vapor region to transport a vapor form of the first fluid from the first wick structure;
a second section comprising second wick structure to carry a liquid form of a second fluid, and a second vapor region to transport a vapor form of the second fluid from the second wick structure;
a third section comprising a phase change material to absorb energy from the vapor form of the first fluid and to absorb energy from the vapor form of the second fluid; and
a barrier to separate the third section from the first section and the second section.

20. The heat dissipating apparatus of claim 19, further comprising:
a heat sink to transfer energy from the third section; and
a cooling fan.
